(19) United States
(12) Patent Application Publication
(10) Pub. No.: US 2016/0141492 A1
(43) Pub. Date: May 19, 2016

(54) MEMRISTOR AND METHODS FOR MAKING THE SAME

(71) Applicant: HEWLETT-PACKARD DEVELOPMENT COMPANY, L.P., Houston, TX (US)

(72) Inventors: Xia Sheng, Palo Alto, CA (US); Xuema Li, Palo Alto, CA (US); Sity Lam, Palo Alto, CA (US)

(21) Appl. No.: 14/898,503

(22) PCT Filed: Jul. 31, 2013
(86) PCT No.: PCT/US2013/052813

§ 371 Date: Dec. 15, 2015

(51) Int. Cl. H01L 45/00; H01L 27/24

(52) U.S. Cl. CPC H01L 45/085; H01L 27/2463; H01L 45/1233; H01L 45/1253; H01L 45/146; H01L 45/145; H01L 45/142; H01L 45/16

(57) ABSTRACT

An example of the memristor includes a bottom electrode, a switchable material positioned on the bottom electrode, and a cured negative or positive resist that forms an interlayer dielectric positioned on the switchable material. An open area is formed in the interlayer dielectric. The open area exposes a surface of the switchable material. A top electrode is positioned in contact with the exposed surface of the switchable material at the open area.

### BACKGROUND

Nanometer-scale crossed-wire switching devices have been reported that can be switched repeatedly. One example is a memristor, which is a type of passive circuit element that maintains a relationship between the time integrals of current and voltage across the crossed wires. Crossed-wire switching devices have been used to construct crossbar circuits, and provide a promising route for the creation of ultra-high density nonvolatile memory and systems with dynamic/synaptic logic. A latch (which is a component for logic circuits and for communication between logic and memory) has been fabricated from a series connection of crossed-wire switches. Logic families have been constructed entirely from crossbar arrays of switches or as hybrid structures composed of switches and transistors. These logic families have the potential to dramatically increase the computing efficiency of CMOS circuits.

### BRIEF DESCRIPTION OF THE DRAWINGS

Features and advantages of examples of the present disclosure will become apparent by reference to the following detailed description and drawings, in which like reference numerals correspond to similar, though perhaps not identical, components. For the sake of brevity, reference numerals or features having a previously described function may or may not be described in connection with other drawings in which they appear.

FIG. 1 is a flow diagram illustrating an example of a method for making an example of a memristor using a negative tone resist;

FIGS. 2A and 2B are cross-sectional, schematic views which together illustrate an example of the method of FIG. 1, utilizing electron-beam lithography, laser lithography, or ion-beam lithography for making an example of the memristor;

FIGS. 3A and 3B are cross-sectional, schematic views which together illustrate another example of the method of FIG. 1, utilizing photolithography for making the example of the memristor;

FIGS. 4A through 4D are cross-sectional, schematic views which together illustrate yet another example of the method of FIG. 1, utilizing nanoimprint lithography for making the example of the memristor;

FIGS. 5A through 5C are cross-sectional, schematic views which together illustrate an example of the method of FIG. 1 for making another example of the memristor;

FIGS. 6A and 6B are cross-sectional, schematic views which together illustrate an example of a method for making an example of an electronic device;

FIG. 7 is a flow diagram illustrating an example of a method for making an example of a memristor using a positive tone resist;

FIG. 8 is a semi-schematic perspective view of a memristor according to an example of the present disclosure; and

FIG. 9 is a schematic perspective view of a crossbar array according to an example of the present disclosure.

### DETAILED DESCRIPTION

Examples of the method disclosed herein provide a fabrication process for electronic devices, such as a memristor. One example of the method advantageously involves the simultaneous patterning and processing of a negative resist (i.e., a negative tone resist). This single step generates an interlayer dielectric (ILD) that is included in the resulting memristor and also creates bit area(s). Another example of the method advantageously involves a two-step patterning and processing of a positive resist (i.e., a positive tone resist). This two-step process generates an interlayer dielectric (ILD) that is included in the resulting memristor and also creates bit area(s). The methods disclosed herein streamline the memristor fabrication process, by eliminating separate steps that are common in other processes, such as bit patterning with a sacrificial material, growth or deposition of an interlayer dielectric material around the sacrificial material, opening or exposing the bits by removing the sacrificial material, etc.

As used herein, the term “negative resist” refers to any material that polymerizes and cross-links upon exposure to a beam of electrons, a beam of ions, ultraviolet (UV) light, and/or heat. Areas of the negative resist that are exposed to one or more of these stimuli become cross-linked and polymerized, and thus are more difficult to remove (e.g., by dissolution) than areas of the negative resist that are not exposed. Specific examples of the negative resist will be discussed hereinbelow.

Also as used herein, the term “positive resist” refers to a material that when exposed to UV light becomes soluble to a photoresist developer. The portion of the photoresist that is unexposed remains insoluble to the photoresist developer, and can be hard baked after development to form the interlayer dielectric.

Furthermore, the terms “disposed on”, “deposited on”, or the like are broadly defined herein to encompass a variety of divergent connected arrangements and assembly techniques. These arrangements and techniques include, but are not limited to (1) the direct connection between one component and another component with no intervening components therebetween (e.g., the negative resist in direct contact with an electrode surface); and (2) the connection of one component and another component with one or more components therebetween (e.g., the negative resist positioned on a switching layer that is in direct contact with an electrode surface). In some instances, one component disposed or deposited on the other component is somehow in operative communication with the other component (notwithstanding the presence of one or more additional components therebetween).

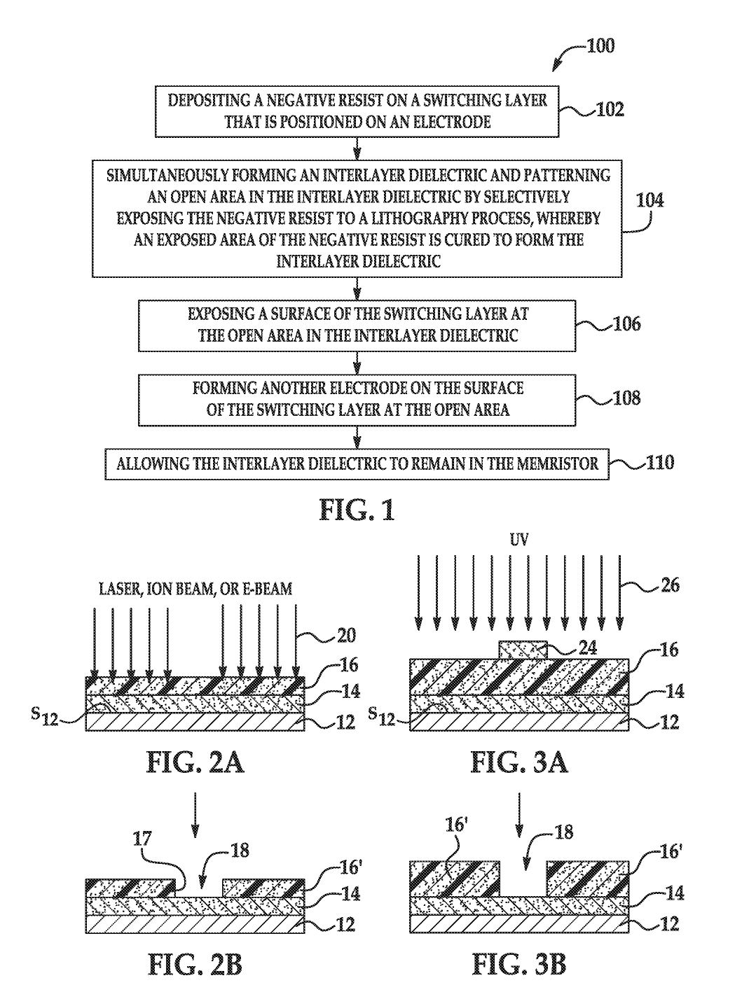

Referring now to FIG. 1, an example of the method 100 is depicted. Generally, the method 100 includes depositing a negative resist on a switching layer that is positioned on an electrode, as shown at reference numeral 102, and simultaneously forming an interlayer dielectric and patterning an open area in the interlayer dielectric by selectively exposing the negative resist to a lithography process, as shown at reference numeral 104. It is to be understood that in the step shown at reference numeral 104, an exposed area of the negative resist is cured to form the interlayer dielectric. The method 100 also includes, as shown at reference numeral 106, exposing a surface of the switching layer at the open area in the interlayer dielectric. As depicted at reference numeral 108, another electrode is formed on the surface of the switching layer at the open area. The interlayer dielectric is allowed to remain in the memristor, as shown at reference numeral 110.

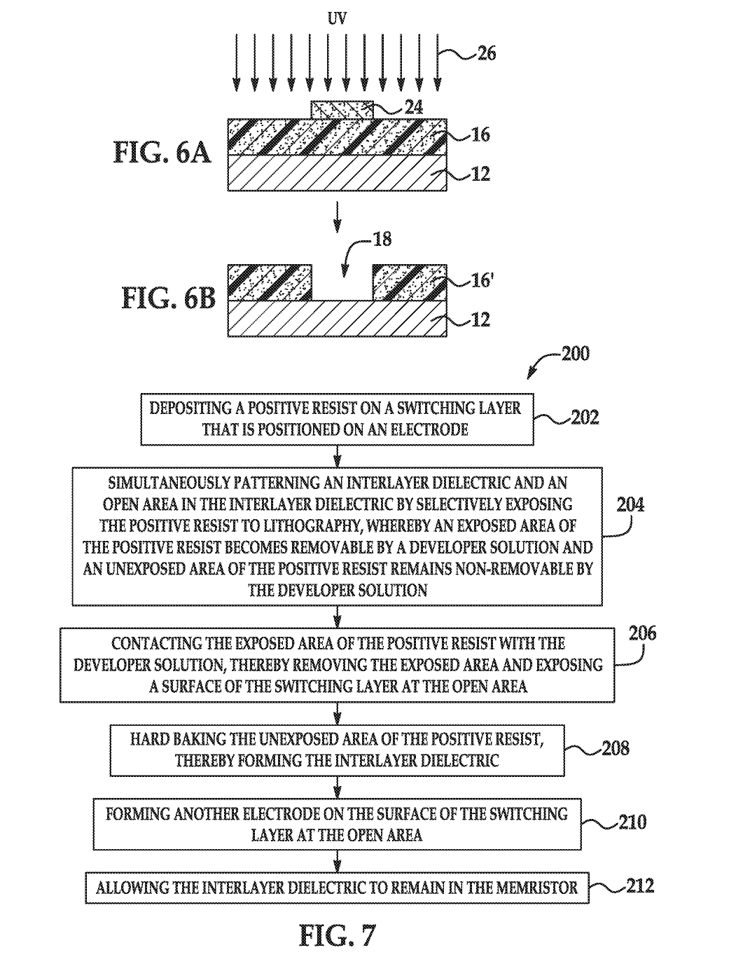

The method shown in FIG. 1 may be implemented using a variety of techniques and materials, and some examples are described in more detail with reference to FIGS. 2A and 2B, 3A and 3B, 4A-4D, 5A-5C, and 6A and 6B. FIGS. 2A and 2B, 3A and 3B, 4A-4D, and 5A-5C respectively depict different examples of the method for forming a memristor, and FIGS. 6A and 6B depict an example of the method for opening up a contact pad. Each of FIGS. 2A and 2B, 3A and 3B, 4A-4D, 5A-5C, and 6A and 6B discusses the method 100 using a negative resist. It is to be understood that a positive resist may also be used to form a memristor, FIG. 7, discussed below, illustrates yet another example of the method for making the memristor utilizing a positive resist.

Referring now to FIGS. 2A and 2B, an example of the method is depicted in which laser, electron beam (e-beam), or ion beam lithography is used to simultaneously form the interlayer dielectric and pattern an open area. At FIG. 2A, an electrode 12 is depicted having a switching material/layer 14 established on a surface S₁₂ thereof and a negative resist 16 established on the switching material/layer 14.

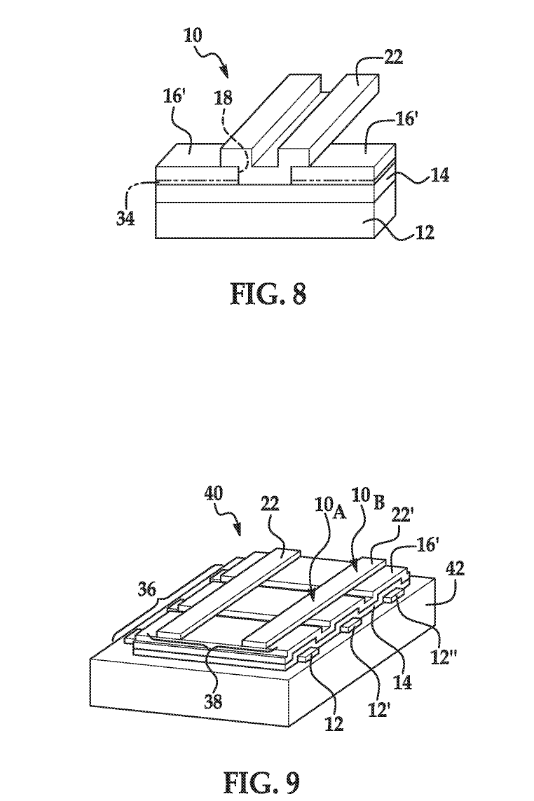

The electrode 12 may be formed of any suitable conductive material (e.g., gold, platinum, tungsten, aluminum, copper, titanium nitride, tantalum nitride, etc.), and may have any suitable thickness (e.g., ranging from about 5 nm to about 100 nm). The electrode 12 (as well as the electrode 22 discussed below and shown in FIG. 8) may be a single layer having a single-component composition, a single layer with a multi-component composition, or a multi-layered structure with different materials in each of the layers. The electrode 12 may be fabricated using any suitable technique, such as photolithography, electron beam lithography, imprint lithography, thermal or e-beam evaporation, sputtering, atomic layer deposition (ALD), or the like. Although the electrode 12 is shown with a rectangular cross-section, it is to be understood that the electrode 12 may also have a circular, an elliptical, or another more complex cross-section. The electrode 12 may also have many different widths or diameters and aspect ratios or eccentricities.

The switching material 14 may be any material that is capable of switching between low resistance and high resistance states in response to an applied current.

In an example, the switching material 14 material is made up of an oxide, nitride, or sulfide having defects (e.g., oxygen vacancies, nitride vacancies, or sulfide vacancies, respectively) therein. Examples of these materials include TiO₂ and TiO₂ (where 0<x<2), Ta₂O₅ and Ta₂O₅₋ₓ (where 0<x<5), NiO₂ and NiO₂₋ₓ (where 0<x <2), GaN and GaNᵢ₋ₓ (where 0<x<1), ZrO₂ and ZrO₂₋ₓ (where 0<x<2), HfO₂ and HfO₂₋ₓ (where 0<x<2), or SrTiO₃ and SrTiO₃₋ₓ (where 0<x<3), or Cu₂S and CuS₂₋ₓ (where 0<x<1), or copper sulfides, where the ratio of Cu to S in the non-vacancy rich portion can range from 0.5 to 2 (i.e., from CuS₂ to Cu₂S) and where the ratio of Cu to S in the vacancy rich portion can range, respectively, from CuS₂₋ₓ (where 0<x<2) to Cu₂Sₓ (where 0<x<1). The defects are generally introduced or formed at an interface near the electrode 12 or at an opposed interface (i.e., a portion of the switching material 14 is rich in vacancies (e.g., TiO₂)). The other of these interfaces remains substantially void of defects (i.e., another portion of the switching material 14 has little or no defects therein, and as such, has a resistivity of more than 10⁴ ohm-cm (e.g., TiO₂)). In the final device (an example of which is shown as reference numeral 10 in FIG. 8) including this type of switching material 14, upon application of a suitable voltage for ON switching (e.g., to a low resistance state), the defects drift towards whichever interface is substantially void of defects, thereby creating localized conductance channels across the switching material 14. For OFF switching, the opposite voltage polarity is applied, and the defects retreat from that interface to switch the device 10 to a high resistance state.

Suitable deposition techniques for the oxide, nitride, or sulfide material include conventional physical and chemical techniques, including evaporation from a heated source, such as a filament or a Knudsen cell, electron beam (i.e., e-beam) evaporation from a crucible, sputtering from a target, other forms of evaporation, chemical vapor deposition (CVD), molecular beam deposition, atomic layer deposition, pulse laser deposition, or various other forms of chemical vapor or beam growth from reactive precursors. Appropriate deposition or growth conditions, such as speed and temperature, may be selected to achieve the desirable chemical composition and local atomic structure desired for the switching material 14.

The defects may be introduced after the oxide, nitride, or sulfide material has been deposited, or during deposition of the oxide, nitride, or sulfide material. In an example, dopant initiators may be diffused from a region or source into the oxide, nitride, or sulfide material, where they react with a portion (e.g., a few nanometers or less) of the oxide, nitride, or sulfide material. This chemical reaction forms the defects at the interface between the remaining oxide, nitride, or sulfide material and the electrode 12. Examples of dopants that result from the chemical reaction include interstitials, vacancies or other charged impurities. Such mobile dopants are positively or negatively charged. In an example, titanium (e.g., a suitable dopant initiator) may diffuse through and react with the material, e.g., titanium dioxide. This chemical reaction causes the reduction of a portion of the metal oxide, resulting in the formation of a TiO₂₋ₓ area at an interface between the remaining titanium dioxide and the electrode 12. This TiO₂₋ₓ area has a small deficit of oxygen atoms in the crystal structure, and the sites (where the missing oxygen atoms would be) are positively charged vacancies, or defects/mobile dopants.

In another example, the switching material 14 is made up of layers formed with a precise defect concentration so that the switching material 14 exhibits a desirable defect concentration profile when the device 10 is in an OFF state. In this example, the layers of the switching material 14 are formed via ALD, which involves sequential pulsing of different chemical precursor vapors, both of which form about one atomic layer per pulse. By varying the temperature continuously from one cycle (layer) to the next, one can achieve a desirable continuous defect gradient throughout the switching material 14.

In another example, the switching material 14 material is undoped TiO₂ or another undoped transition metal oxide. In this example, the switching material 14 includes the insulating oxide with a narrow conductive channel (having a width of 100 nm or less) formed therein (e.g., through the thickness of the switching material 14 and adjacent to the open area 18, which is discussed below), When current flows through the channel, the surrounding insulating oxide is heated, which causes a phase transition in the surrounding insulating oxide. In this example of the switching layer 14, the heat induces a Mott transition (localized electron clouds begin to overlap), which initiates a sudden increase in conductivity.

The switching layer 14 may be a single layer of a single composition, or it may be a single layer with a multi-component composition (e.g., silicon doped with Ta₂O₅₋ₓ), or it may include stacked layers (e.g., a TiO₂/TaOₓ stack or a NbOₓ/TaOₓ stack).

In the example shown in FIG. 2A, the negative resist 16 is deposited on the switching material 14. Examples of the negative resist 16 for this example of the method include negative tone e-beam or ion-beam resists, such as HSQ (hydrogen silsesquioxane) from Dow Corning, mA-N2400 series resist from Micro Resist Technology, and some metal oxide resists (e.g., Al₂O₃, WO₃, ZnO, TiOₓ). The negative resist 16 in this example may also be a thermally curable material that is curable by a focus laser beam.

The negative resist 16 may be deposited on the switching material 14 by spin coating from a solution, or sputtering from a target. For example, the HSQ and mA-N2400 can be spin coated, and the metal oxides materials can be either sputtered on a substrate using a conventional rf reactive sputtering process or can be spin coated using colloids or naphthenates. Metal naphthenates are stable viscous liquids at room temperature and consist of cyclopentanes or cyclohexanes, methylene chains [—(CH₂)—], carboxylates, and metals. Under e-beam exposure, the naphthenate molecules are cross-linked, which increases the molecular weight of the resist 16, rending it insoluble in a developer.

It is to be understood that more than one coating of the negative resist 16 (of the same kind or of different kinds as long as they are laser, e-beam, or on beam resists) may be deposited to reduce or eliminate defects, such as pinholes. The total thickness of the applied negative resist(s) 16 ranges from about 20 nm to about 200 nm.

In this example of the method, laser, e-beam, or on beam lithography is used to simultaneously form the interlayer dielectric 16′ (FIG. 2B) and pattern an open area 18 (FIG. 2B). As shown in FIG. 2A, portions of the negative resist 16 are exposed to laser beams, e-beams, or ion beams 20 while other portions of the negative resist 16 are not exposed to the laser beams, e-beams, or ion beams 20. The dose to which the negative resist 16 is exposed is dependent, at least in part, upon the species of the negative resist 16, the species of the charged particles of the beam, and the energy of the beam. The exposed portions are cured and form the interlayer dielectric 16′ shown in FIG. 2B.

The unexposed portions remain uncured and are readily removable using a suitable developer solution that dissolves the uncured negative resist 16. The developer solution that is used to remove any unexposed portions may depend upon the negative resist 16 that is used, Examples of developer solutions include NaOH, KOH, MICROPOSIT® MF® CD-26 (available from Rohm and Haas Electronic Materials LLC), tetramethyl ammonium hydroxide (TMAH), ma-D 525 (available from Micro Resist Technology), or organic solvents, such as acetone or N-methyl-2-pyrrolidone (NMP).

Upon removal of the unexposed negative resist 16, the open area 18 is formed and a surface of the switching material 14 within this open area 18 is exposed. In the final device that is formed, this open area 18 is a bit area. When laser, e-beam, or ion beam lithography is performed, the desired pattern for the bit areas may be formed in the negative resist 16 by not exposing those areas of the negative resist 16 to the beams.

Since the open area 18 is the bit area for the memristor, the dimensions of the bit area are defined by the size and shape of the open area 18. The resulting open area 18 may have any desirable shape, including, as examples, the shape of a hole (e.g., a cylindrical shape) or a trench (e.g., a rectangular or cubic shape).

In some instances, it may be desirable to further shrink the length and/or width of the open area(s) 18. This may be accomplished by conformally growing a dielectric material (not shown) in the open area 18 so that the dielectric material is positioned within the open area 18 and adjacent to sidewall(s) 17 of the interlayer dielectric 16′. Examples of conformal growth techniques include plasma enhanced chemical vapor deposition (PECVD) and ALD. Anisotropic reactive ion etching is then used to remove some of the dielectric material from the open area 18. The anisotropic reactive ion etch allows the selective removal of the dielectric material from within part of the open area 18 in order to again expose the surface of the switching material 14 while leaving some of the dielectric material on the sidewall(s) 17.

The example of the method shown in FIGS. 2A and 2B may be particularly suitable for forming open area(s) 18 having a length and/or width ranging from about 4 nm to about 200 nm. In another example, the method shown in FIGS. 2A and 2B may be particularly suitable for forming open area(s) 18 having a length and/or width that is 54 nm or less.

After creating the open area 18, another electrode (not shown in FIG. 2B, but shown at reference numeral 22 in FIG. 8) may be deposited in the open area 18 on the surface of the switching material 14. In an example, the other electrode is deposited in the open area 18 and at least partially fills the open area 18, and in another example, the other electrode is deposited in the open area 18 such that the electrode material fills the open area 18 and extends onto the surface of the interlayer dielectric 16′. The other electrode may be formed of any of the materials and by any of the process described for electrode 12.

Referring now to FIGS. 3A and 3B, an example of the method is depicted in which photolithography is used to simultaneously form the interlayer dielectric 16′ and pattern the open area 18. As shown in FIG. 3A, the electrode 12 has the switching material 14 established on the surface S₁₂, and the negative resist 16 established on the switching material 14. It is to be understood that the materials and processes for forming the electrode 12 and the switching material 14 previously described in reference to FIGS. 2A and 2B may be used in this example of the method.

In the example shown in FIG. 3A, the negative resist 16 is deposited on the switching material 14. Examples of the negative resist 16 for this example of the method include any negative tone photolithographic resist. Specific examples include epoxy-based polymer resists, such as SU-8 from MicroChem, polyhydroxystyrene-based polymers, and an EUV (extreme ultraviolet lithography) resist.

The negative resist 16 in this example may be deposited on the switching material 14 by spin coating, spray coating, dip coating, gravure coating, or the like. It is to be understood that more than one coating of the negative resist 16 (of the same kind or of different kinds as long as they are photolithographic) may be deposited to reduce or eliminate defects, such as pinholes. For example, an under-layer dielectric (as described in reference to FIGS. 5A through 5C) may be used in the example shown in FIGS. 3A -3B. The total thickness of the applied negative resist(s) 16 in this example ranges from about 20 nm to about 200 nm.

In this example of the method, photolithography is used to simultaneously form the interlayer dielectric 16′ (FIG. 3B) and pattern an open area 18 (FIG. 3B).

As shown in FIG. 3A, a photomask 24 is positioned on or over the negative resist 16 to prohibit the UV light beams 26 from reaching the negative resist 16. Examples of the photomask 24 may be formed of Cr or Fe₂O₃. The configuration of the photomask 24 is identical to the desired pattern of the open area(s) 18 that will ultimately be formed. Once the photomask 24 is in place, UV light beams are directed at the surface of the negative resist 16. As illustrated in FIG. 3A, the photomask 24 will block the UV light beams 26 so that portions of the negative resist 16 between the photomask 24 and the UV light source (not shown) are not exposed to the beams 26. At the same time, those portions of the negative resist 16 that are not covered by the photomask 24 will be exposed to the UV light beams 26. Exposure time and/or dose may vary depending upon the resist 16 that is used. The exposed portions are cured and form the interlayer dielectric 16′ shown in FIG. 3B.

After photolithography is complete, the photomask 24 is removed.

The unexposed portions of the negative resist 16 remain uncured and are readily removable using a suitable developer solution that dissolves the uncured portions. The developer solution that is used to remove any unexposed portions may depend upon the negative resist 16 that is used. Examples of developer solutions for this example of the method include TMAH or 1-methoxy-2-propanol acetate.

Upon removal of the unexposed negative resist 16, the open area 18 is formed and a surface of the switching material 14 within this open area 18 is exposed. In the final device that is formed, this open area 18 is a bit area. As such, when photolithography is performed, the desired pattern for the bit areas may be formed in the negative resist 16 by not exposing those areas of the negative resist 16 to the UV light beams or heat 24.

After creating the open area 18, another electrode (not shown in FIG. 3B, but shown at reference numeral 22 in FIG. 8) may be deposited in the open area 18 on the exposed surface of the switching material 14. In an example, the other electrode is deposited in the open area 18 such that the electrode material at least partially fills the open area 18, and in another example, the other electrode is deposited in the open area 18 such that the electrode material fills the open area 18 and extends onto the surface of the interlayer dielectric 16′. The other electrode may be formed of any of the materials and by any of the process described for electrode 12,

In some instances, it may be desirable to perform a surface cleaning process before depositing the other electrode 22. The surface cleaning process may include an O₂ or Ar plasma cleaning or a solvent cleaning.

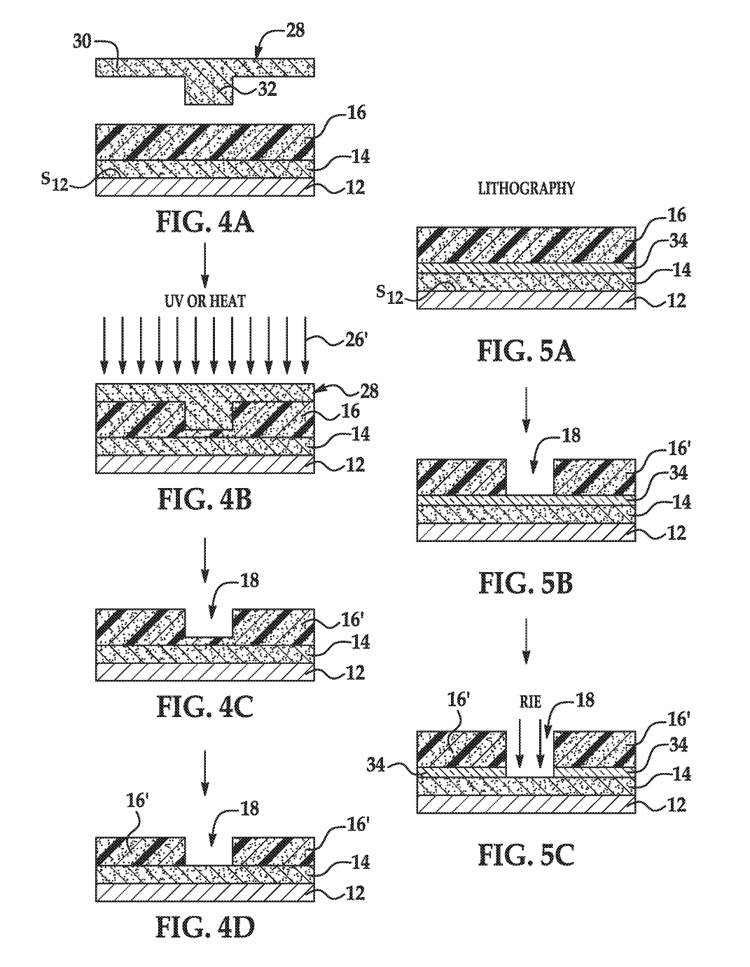

Referring now to FIGS. 4A through 4D, an example of the method is depicted in which nano-imprint lithography is used to simultaneously form the interlayer dielectric 16′ and pattern the open area 18. As shown in FIG. 4A, the electrode 12 has the switching material 14 established on the surface S₁₂, and the negative resist 16 established on the switching material 14. It is to be understood that the materials and processes for forming the electrode 12 and the switching material 14 previously described in reference to FIGS. 2A and 2B may be used in this example of the method.

In the example shown in FIG. 4A, the negative resist 16 is an imprint resist that is deposited on the switching material 14. The imprint resist is typically a monomer or polymer formulation that is cured by heat or UV light during the imprinting. Examples of the imprint resist for this example of the method include the mr-UVCur series from Micro Resist Technology and the nano-imprint lithography resists sold by Nanonex.

The imprint resist (i.e., negative resist 16 in this example) may be deposited on the switching material 14 by spin coating, spray coating, dip coating, gravure coating, or the like. It is to be understood that more than one coating of the imprint resist (of the same kind or of different kinds as long as they are nano-imprint lithography resists) may be deposited to reduce or eliminate defects, such as pinholes. The total thickness of the applied negative resist(s) 16 in this example ranges from about 20 nm to about 200 nm.

A nano-imprint mold 28 may be used to form the pattern for the open area 18. The nano-imprint mold 28 includes a base 30 and a feature 32 protruding from the base. The feature(s) 32 of the mold 28 are configured so that when the nano-imprint mold 28 is utilized to imprint the imprint resist 16, the feature(s) 28 define the desired open area(s) 18. As such, the feature(s) 32 of the mold 28 are a negative replica (or the inverse) of the open area(s) 18.

The mold base 30 may be include silica, silicon, quartz, gallium arsenide, or any other suitable metal, ceramic, or polymer material. In an example, the mold 28 is formed of a material that enables UV light beams or heat to penetrate or transmit through the mold 28. The feature(s) 32 of the mold 28 may be formed in the surface of the mold base 30 using, for example, electron beam lithography, reactive ion etching, or any other wet or dry chemical etching method that results in the formation of feature(s) protruding from the surface of the mold base 30.

As shown in FIG. 4B, the nano-imprint mold 28 is pressed into the imprint resist (i.e., negative resist 16 in this example of the method). It is to be understood that the imprinting may be a single step imprint, a step-and-repeat imprint, or a roll-to-roll imprint. While the mold 28 is positioned in the imprint resist, the imprinted resist may be exposed to UV light beams or heat 26′, depending upon the type of resist used. This exposure cures the imprint resist to form the interlayer dielectric 16′. The time and/or dosage of the exposure may be long enough for the resist 16 to fully cure (i.e., completely cure or cross-link). The position of the mold 28 during curing also patterns the open area 18.

After the nano-imprint lithography is complete, the nano-imprint mold 28 may be separated from the interlayer dielectric 16′, as shown in FIG. 4C.

In this example, all of the imprint resist is exposed to the UV light beams or heat 26′, and thus is cured. As shown in FIG. 4C, this may result in some of the interlayer dielectric 16′ being present in the open area 18. As such, it may be desirable to perform reactive ion etching (or some other suitable etching technique) to remove the portion of the interlayer dielectric 16′ in the open area 18 in order to expose the surface of the switching material 14 in the open area 18. The result of this etching process is shown in FIG. 4D. It is to be understood that reactive ion etching may be anisotropic so that the open area 18 is not widened. The time for etching may depend, at least in part, on the amount of the interlayer dielectric 16′ that is present in the open area 18.

In the final device that is formed, the open area 18 is a bit area. As such, when nano-imprint lithography is performed, a negative replica of the desired pattern for the bit area(s) may be formed in the mold 28.

After exposing the surface of the switching layer 14 at the open area 18, another electrode (not shown in FIG. 4D, but shown at reference numeral 22 in FIG. 8) may be deposited in the open area 18 on the exposed surface of the switching material 14. In an example, the other electrode is deposited in the open area 18 such that the electrode material at least partially fills the open area 18, and in another example, the other electrode is deposited in the open area 18 such that the electrode material fills the open area 18 and extends onto the surface of the interlayer dielectric 16′. The other electrode may be formed of any of the materials and by any of the process described for electrode 12.

FIGS. 5A through 5C illustrate still another example of the method. As shown in FIG. 5A, the electrode 12 has the switching material 14 established on the surface S₁₂. It is to be understood that the materials and processes for forming the electrode 12 and the switching material 14 previously described in reference to FIGS. 2A and 2B may be used in this example of the method.

In this example, an under-layer dielectric 34 is positioned on the switching material 14, and thus is deposited prior to the negative resist 16. In an example, the under-layer dielectric 34 may be an inorganic dielectric material, such as SiO₂, Si₃N₄, Al₂O₃, Ta₂O₃, ZrO₂, or combinations of these materials. These inorganic under-layer dielectrics 34 may be deposited using PECVD, sputtering, ALD, or electron beam (e-beam) evaporation. In another example, the under-layer dielectric 34 may be an organic or inorganic polymer based materials, such as UV curable polymers (e.g., polyimide) or spin-on-glass. These under-layer dielectrics 34 may be deposited using spin coating, dip coating, or the like. A suitable thickness for the under-layer dielectric 34 ranges from about 10 nm to about 50 nm.

In the example shown in FIG. 5A, the negative resist 16 is deposited on the under-layer dielectric 34. For this example, any negative tone laser, e-beam, or ion beam resist, or photolithographic resist, or imprint resist may be used. The negative resist 16 in this example may be deposited on the under-layer dielectric 34 by any technique that is suitable for the selected type of resist.

As shown in FIG. 5A, the negative resist 16 is exposed to one of the lithography techniques previously described in reference to FIGS. 2 through 4, so that the open area 18 (shown in FIG. 5B) is formed.

In the example method shown in FIGS. 5A through 5C, the under-layer dielectric 34 is a cured layer that is not affected by any additional lithography process. When this type of under-layer dielectric 34 is utilized, the uncured negative resist 16 is removed, for example, by dissolution, the entire under-layer dielectric 34 and the interlayer dielectric 16′ remain, as shown in FIG. 5B.

The switching layer 14 in the open area 18 may then be exposed by removing the under-layer dielectric 34 that is present in the open area 18. This may be accomplished by reactive ion etching (RIE), where the interlayer dielectric 16′ functions as a mask because it (unlike the under-layer dielectric 34) is not susceptible to the etching process. In an example, HSQ is used as the negative resist 16/interlayer dielectric 16′, Ta₂O₅ is used as the under-layer dielectric 34, and Cl₂ is used as the etching gas.

As shown in FIG. 5C, after the reactive ion etching process is complete, the remaining under-layer dielectric 34 functions as a second dielectric layer in the device, and is not removed. This double dielectric layer system can effectively reduce the leakage current and increase the breakdown voltage. When the under-layer dielectric 34 is included, the negative resist 16 may be a little thinner (e.g., as compared to the thickness when the under-layer dielectric 34 is not used) to ensure good lithography resolution.

After creating the open area 18 and exposing the surface of the switching layer 14, another electrode (not shown in FIG. 5C, but shown at reference numeral 22 in FIG. 8) may be deposited in the open area 18 on the exposed surface of the switching material 14. In an example, the other electrode is deposited in the open area 18 such that the electrode material at least partially fills the open area 18, and in another example, the other electrode is deposited in the open area 18 such that the electrode material fills the open area 18 and extends onto the surface of the interlayer dielectric 16′. The other electrode may be formed of any of the materials and by any of the process described for electrode 12.

It is to be understood that in the example method shown in FIGS. 5A through 5C, the under-layer dielectric 34 may be selected so that exposed portions cross-link during the lithography process. This is a double layer negative tone resist process, where the first layer of negative resist is not washed away when the second layer of negative resist is coated. When this type of under-layer dielectric 34 is selected, any of the under-layer dielectric 34 that is positioned beneath the mask 24 during lithography (i.e., is not exposed to the suitable stimulus) will not be cured. In this example then, the uncured portions of the under-layer dielectric 34 may be removed with the uncured portions of the negative resist 16, and the additional etching process will not be necessary to expose the surface of the switching material 14 at the open area 18.

Referring now to FIGS. 6A and 6B, still another example of the method is depicted. While photolithography is shown, it is to be understood that this example may be performed using laser lithography, e-beam lithography, ion beam lithography, or nano-imprint lithography.

As shown in FIG. 6A, the negative resist 16 is deposited directly on the electrode 12. The negative resist 16 may be selected according to the lithography technique that is being used, and may be deposited via spin coating.

In the example shown in FIG. 6A, photolithography is performed in the manner previously described. In this example, the photomask 24 enables the selective exposure of the negative resist 16 to the UV light beams 26. In particular, those portions of the negative resist 16 beneath the photomask 24 are not exposed to the UV light beams 26. At the same time, those portions of the negative resist 16 that are not covered by the photomask 24 will be exposed to the UV light beams 26. The exposed portions are cured and form the interlayer dielectric 16′ shown in FIG. 6B. After photolithography is complete, the photomask 24 is removed.

The unexposed portions of the negative resist 16 remain uncured and are readily removable using a suitable developer solution that dissolves the uncured portions. In this example, the developer solution is selected so that the underlying electrode material is not deleteriously affected. Examples of developer solutions for this example of the method include those previously mentioned.

Upon removal of the unexposed negative resist 16, the open area 18 is formed and the surface S₁₂ of the electrode 12 at the open area 18 is exposed. This creates a contact pad for the electrode 12.

All of the previous examples have utilized a negative resist or an imprint resist. FIG. 7 illustrates an example of the method 200 in which a positive resist is used to form the interlayer dielectric 16′. In this example of the method 200 at reference numeral 202, a positive resist is deposited on the switching layer 14, which is positioned on the electrode 12. The electrode 12 and the switching layer 14 may be formed of the materials and using the techniques previously described herein.

An example of a suitable positive resist includes a DNQ-Novolac resist, which is based on a mixture of diazonaphthoquinone (DNC)) and novolac resin (a phenol formaldehyde resin). Other suitable positive resists include the photoresists of the MICROPOSIT® S1800® series (available from Shipley) and the ma-P 1200 series (available from Micro Resist Technology). Polymethyl methacrylate (PMMA) is a versatile polymer and may be used as an e-beam positive resist. One example of a commercially available PMMA is NANO™ PMMA, available from MicroChem. All of the positive resists are capable of being patterned and then hard baked to form the interlayer dielectric 16′.

As shown at reference numeral 204, the positive resist is selectively exposed to lithography (e.g., photolithography or e-beam lithography) in order to simultaneously pattern the interlayer dielectric 16′ and an open area 18 in the interlayer dielectric 16′. The previously described photomask 24 and UV beams 26 or e-beams 20 may be used to perform lithography. In this step, the exposed area of the positive resist becomes removable by a developer solution and the unexposed area of the positive resist remains non-removable by the developer solution. As such, the exposed area is the pattern for the open areas and the unexposed area is the pattern for the interlayer dielectric 16′.

At reference numeral 206, the method 200 involves contacting the exposed area of the positive resist with the developer solution. This will remove the exposed area of the positive resist and will expose the surface of the switching layer 14 at the open area 18.

At reference numeral 208 in this example of the method 200, the unexposed area of the positive resist may be hard baked to form the interlayer dielectric 16′. Hard baking may be accomplished via any suitable method, and the temperature used will depend upon the resist that is selected. In an example, hard baking takes place at a temperature ranging from about 120° C. to about 180° C.

The method 200 involves forming another electrode 22 on the surface of the switching layer 14 at the open area 18, as shown at reference numeral 210. The electrode 22 may be formed of the materials and using the techniques/processes previously described herein. The technique/process selected for electrode 22 fabrication may be a process that will not deleteriously affect the interlayer dielectric 16 that is formed of the positive resist. In an example, this process may be a shadow mask process, where resolution is limited to about 5 μm. In another example, this process may be any electrode fabrication process that does not utilize a solvent that dissolves the positive resist or does not utilize a plasma that removes the positive resist.

The method 200 also involves allowing the interlayer dielectric 16′ to remain in the memristor 10, as shown at reference numeral 212.

The example of the method 200 shown in FIG. 2 may also utilize the under-layer dielectric 34 on the switching material 14. In this example, the under-layer dielectric 34 is deposited before the positive resist, and after the exposed areas of the positive resist are exposed to the developer solution but before the other electrode 22 is formed, any of the under-layer dielectric 34 that is present in the open area 18 is etched away (e.g., as previously described). This will expose the surface of the switching layer 14.

This example of the method 200 may also include shrinking the open area 18 by conformally growing a dielectric material in the open area 18 such that the dielectric material is in contact with a side wall 17 of the interlayer dielectric 16′, and then exposing the dielectric material to an anisotropic reactive ion etch to remove some of the dielectric material and to leave some other of the dielectric material on the side wall 17 of the interlayer dielectric 16′.

In any of the examples of the method disclosed herein, the interlayer dielectric 16′ may be exposed to additional surface treatments. Suitable surface treatments include those processes that improve the dielectric properties of the interlayer dielectric 16′, such as lowering the leakage current, increasing the break-down electric field, or changing the dielectric constant as desired. Example surface treatments include thermal annealing in vacuum or gas, or a plasma chemical treatment with a gas species, such as O₂, NH₃, H₂, N₂ or a mixture of these gases. These treatments may be carried out at room temperature (e.g., from about 18° C. to about 25° C.) or a higher temperature, such as 300° C.

Referring now to FIG. 8, an example of the memristor 10 that may be formed via the methods shown in FIGS. 2-5 or in FIG. 7 is depicted. As illustrated, the memristor 10 includes the electrode 12 (which is a bottom electrode in this example), the switching layer 14, the interlayer dielectric 16′, and the other electrode 22 (which is a top electrode in this example) formed in the open area 18 and on a portion of the interlayer dielectric 16. In an example (as shown in FIG. 8), the other electrode 22 may be positioned at a non-zero angle with respect to the position of the electrode 12. In some examples, the device 10 may also include the under-layer dielectric 34, as shown in phantom.

Referring now to FIG. 9, an example of a crossbar array 40 including multiple memristors 10 (two of which are labeled 10_{A} and 10_{B}) is depicted. It is to be understood that the materials described herein may be used in the memristors 10_{A}, O_{B} of the crossbar array 40.

Generally, the crossbar 40 is an array of switches wherein each electrode 12, 12′, 12″ in one set 36 of parallel electrodes is operatively connected to every electrode 22, 22′ in a second set 38 of parallel electrodes that intersects the first set 36. In many instances, the two sets 36, 38 of electrodes 12, 12′, 12″, 22, 22′ are perpendicular to each other. However, this is not a necessary condition, and the two sets 36, 38 of electrodes 12, 12′, 12″, 22, 22′ may be offset at any non-zero angle.

Where any of the electrodes 12, 12′, 12″ cross the electrode 22, 22′, a cross-point is formed. It is to be understood that each of the cross-points in the crossbar 40 includes a respective open area 18 (in this example, a bit area) where a respective electrode 12, 12′, 12″ is operatively connected to the crossing electrode 22, 22′ through the switching material 14 positioned therebetween. The switching material 14 at each cross-point is individually addressable after initial fabrication by virtue of the respective electrodes 12, 12′, 12″, 22, 22′ being in selective electrical contact with the switching material 14. For example, if electrodes 12′ and 22′ are addressed with an appropriate voltage and polarity, memristive device 10_{A} is activated and switched to either the ON state or the OFF state, and if electrodes 12″ and 22′ are addressed with an appropriate voltage and polarity, memristive device 10_{B} is activated and switched to either the ON state or the OFF state. In the array 40, it is to be understood that when one or more individual devices 10 are addressed, the switching material 14 positioned outside of the cross-point that is being addressed remain inactive, as essentially no voltage is applied therebetween (e.g., a voltage is not directly applied to such areas).

As shown in FIG. 9, the devices 10_{A}, 10_{B} are disposed on a substrate 42. Examples of the substrate 42 include a silicon wafer having a silicon dioxide layer disposed thereon, aluminum oxide, strontium titanate, magnesium oxide, gallium nitride, aluminum nitride, gallium arsenide, germanium, other non-oxide insulators, and combinations thereof. Any of the examples of the memristor 10 disclosed herein may be disposed on a substrate 42.

The crossbar 40 may also include stacked memristors (i.e., two or more memristors stacked upon one another). For example, an additional layer of switching material may be formed on the second set 38 of parallel electrodes, another interlayer dielectric may be formed on the additional switching material layer, and then another set of electrodes (e.g., parallel to set 36 and perpendicular to set 38) may be deposited on the other interlayer dielectric (and in any open areas of the other interlayer dielectric).

Reference throughout the specification to “one example”, “another example”, “an example”, and so forth, means that a particular element (e.g., feature, structure, and/or characteristic) described in connection with the example is included in at least one example described herein, and may or may not be present in other examples. In addition, it is to be understood that the described elements for any example may be combined in any suitable manner in the various examples unless the context clearly dictates otherwise.

In describing and claiming the examples disclosed herein, the singular forms “a”, “an”, and “the” mean at least one, and thus include plural referents unless the context clearly dictates otherwise.

It is to be understood that the ranges provided herein include the stated range and any value or sub-range within the stated range. For example, a range from about 20 nm to about 200 nm should be interpreted to include not only the explicitly recited limits of about 20 nm to about 200 nm, but also to include individual values, such as 25.5 nm, 65 nm, 180 nm, etc., and sub-ranges, such as from about 25 nm to about 190 nm, 75 nm to about 150 nm, etc. Furthermore, when “about” is utilized to describe a value, this is meant to encompass minor variations (up to +/−10%) from the stated value.

While several examples have been described in detail, it will be apparent to those skilled in the art that the disclosed examples may be modified. Therefore, the foregoing description is to be considered non-limiting.

What is claimed is:

1. A method for making a memristor, comprising:
depositing a negative resist on a switching layer that is positioned on an electrode;
simultaneously forming an interlayer dielectric and patterning an open area in the interlayer dielectric by selectively exposing the negative resist to a lithography process, whereby an exposed area of the negative resist is cured to form the interlayer dielectric;
exposing a surface of the switching layer at the open area in the interlayer dielectric;
forming an other electrode on the surface of the switching layer at the open area; and
allowing the interlayer dielectric to remain in the memristor.

2. The method as defined in claim 1 wherein the lithography process is selected from the group consisting of photolithography, laser lithography, electron beam lithography, ion beam lithography, and nano-imprint lithography.

3. The method as defined in claim 2 wherein:
the lithography process is nano-imprint lithography involving a nano-imprint mold and ultraviolet curing or thermal curing;
the negative resist is an imprint resist; and
the exposing of the surface of the switching layer is accomplished by performing reactive ion etching to remove cured imprint resist within the open area.

4. The method as defined in claim 2 wherein:
the lithography process is photolithography; and
a photomask is used to selectively expose the negative resist to ultraviolet light such that the negative resist at the open area remains unexposed to the ultraviolet light.

5. The method as defined in claim 4 wherein the exposing of the surface of the switching layer is accomplished by removing the unexposed negative resist at the open area with a developer.

6. The method as defined in claim 1, further comprising shrinking the open area by:
conformally growing a dielectric material in the open area such that the dielectric material is in contact with a side wall of the interlayer dielectric; and
exposing the dielectric material to an anisotropic reactive ion etch to remove some of the dielectric material and to leave some other of the dielectric material on the side wall of the interlayer dielectric.

7. The method as defined in claim 1 wherein:
an under-layer dielectric is positioned between the interlayer dielectric and the switching layer; and
the exposing step includes:
removing uncured negative resist from the open area; and
etching any of the under-layer dielectric that is present in the open area.

8. The method as defined in claim 1, further comprising exposing the interlayer dielectric to a surface treatment selected from the group consisting of thermal annealing in vacuum, thermal annealing in gas, plasma chemical vapor deposition with a gas, and combinations thereof.

9. A method for making a memristor, comprising:
depositing a positive resist on a switching layer that is positioned on an electrode;
simultaneously patterning an interlayer dielectric and an open area in the interlayer dielectric by selectively exposing the positive resist to lithography, whereby an exposed area of the positive resist becomes removable by a developer solution and an unexposed area of the positive resist remains non-removable by the developer solution;
contacting the exposed area of the positive resist with the developer solution, thereby removing the exposed area and exposing a surface of the switching layer at the open area;
hard baking the unexposed area of the positive resist, thereby forming the interlayer dielectric;
forming an other electrode on the surface of the switching layer at the open area; and
allowing the interlayer dielectric to remain in the memristor.

10. The method as defined in claim 9 wherein the other electrode is also formed on the interlayer dielectric.

11. The method as defined in claim 9, further comprising:
depositing an under-layer dielectric on the switching material before depositing the positive resist; and
after contacting the exposed area of the positive resist with the developer solution and before forming the other electrode, etching any of the under-layer dielectric that is present in the open area to expose the surface of the switching layer.

12. The method as defined in claim 9 wherein prior to depositing the second electrode, the method further comprises shrinking the open area by:
conformally growing a dielectric material in the open area such that the dielectric material is in contact with a side wall of the interlayer dielectric; and
exposing the dielectric material to an anisotropic reactive ion etch to remove some of the dielectric material and to leave some other of the dielectric material on the side wall of the interlayer dielectric.

13. A memristor, comprising:
a bottom electrode;
a switchable material positioned on the bottom electrode;
a cured negative or positive resist that forms an interlayer dielectric positioned on the switchable material;
an open area formed in the interlayer dielectric, the open area exposing a surface of the switchable material; and
a top electrode positioned in contact with the exposed surface of the switchable material at the open area.

14. The memristor as defined in claim 13, further comprising an under-layer dielectric positioned between the switchable material and the interlayer dielectric.

15. The memristor as defined in claim 13 wherein the bottom and top electrodes are part of a crossbar array and are positioned at a non-zero angle with respect to each other.
